(19) United States
(12) Patent Application Publication
(10) Pub. No.: US 2026/0292992 A1
(43) Pub. Date: Sep. 24, 2026

(54) METHOD TO INTEGRATE MICRO TRANSFORMERS INTO PRINTED CIRCUIT BOARD FOR STEP-DOWN VOLTAGES

(71) Applicant: Cisco Technology, Inc., San Jose, CA (US)

(72) Inventors: Joel Richard Goergen, Soulsbyville, CA (US); Kameron Rose Hurst, Sonora, CA (US); Hrishikesh Shekhar Pawar, San Jose, CA (US); Rakshitha Salian, San Jose, CA (US); Emanuele Croci, Carate Brianza (MB) (IT); Carolina Hau Loo, Panama (PA); Andrea Brandolese, Milano (IT)

(21) Appl. No.: 19/272,266

(22) Filed: Jul. 17, 2025

Related U.S. Application Data
(60) Provisional application No. 63/775,593, filed on Mar. 21, 2025.

(51) Int. Cl. H05K 1/16; H01F 27/26

(52) U.S. Cl. CPC H05K 1/165; H01F 27/266; H05K 2201/086

(57) ABSTRACT

Micro transformer structures implemented in a printed circuit board (PCB) allow for multiple integrated high voltage to rail step-down transformers in a PCB. These single structures can be added in parallel to provide significant amounts of current. These techniques can achieve a 400V step down to an Application Specific Integrated Circuit (ASIC) rail voltage, or to a voltage level as close as possible to the ASIC rail voltage to minimize or eliminate resistive losses into the PCB.

### CROSS REFERENCE TO RELATED APPLICATION

This application claims priority to U.S. Provisional Application No. 63/775,593, filed Mar. 21, 2025, the entirety of which is incorporated herein by reference.

### TECHNICAL FIELD

The present disclosure relates to power conversion for integrated circuits and printed circuit boards.

### BACKGROUND

The amount of power used by integrated circuits, such as application specific integrated circuits (ASICs) has been increasing for years. For example, in the late 1990s, ASICS used 40 Watts (W) of power, and now ASICs use 1300 W in 2025. One could argue an almost 50 W increase every year since the late 1990s. To move power of that magnitude into a roughly 100 millimeter (mm) by 100 mm area can be challenging.

### BRIEF DESCRIPTION OF THE DRAWINGS

FIG. 1 is a block diagram of a single-step transformer-based voltage conversion arrangement using one or more micro transformers that can be implemented in a printed circuit board (PCB), according to an example embodiment.

FIG. 2A is a cross-sectional view of a micro transformer implemented in a PCB, according to an example embodiment.

FIG. 2B illustrates a three-dimensional view of components of a micro transformer, according to an example embodiment.

FIG. 3 is a cross-sectional view showing a plurality of micro transformers implemented in a PCB and connected in series, according to an example embodiment.

FIG. 4A is a cross-sectional view of a PCB to illustrate formation of a micro transformer structure in a PCB, according to an example embodiment.

FIG. 4B illustrates an isolated cross-sectional view of a transformer core of the micro transformer structure depicted in FIG. 4A, according to an example embodiment.

FIG. 4C illustrates an isolated cross-sectional view of a magnetic material layer forming a part of the transformer core shown in FIG. 4B.

FIG. 4D illustrates an isolated side view of the micro transformer structure depicted in FIG. 4A.

FIG. 4E illustrates a top-down view into the micro transformer structure depicted in FIG. 4D.

FIG. 5A illustrates a cross-sectional view of a PCB, similar to FIG. 4A, showing a transformer structure with two transformer monuments implemented in a PCB, according to an example embodiment.

FIG. 5B shows isolated side views of the two transformer monuments of FIG. 5A.

FIG. 5C is a cross-sectional view of a top plate and a transformer core of the transformer structure shown in FIG. 5A, according to an example embodiment.

FIG. 6A is a diagram showing a current transformer implemented in a PCB comprising a plurality of transformer cores implemented in the PCB, according to an example embodiment.

FIG. 6B illustrates an exploded view of the current transformer shown in FIG. 6A.

FIG. 6C illustrates the current transformer of FIG. 6A with sense lines used for sensing current flowing through an inner conductive layer of the current transformer.

FIGS. 7A and 7B are diagrams illustrating application of a current transformer to implement a two stage electromagnetic interference (EMI) filter, according to an example embodiment.

FIG. 8A is a schematic diagram of a hall effect sensor configured to be integrated into a current transformer implemented in a PCB, according to an example embodiment.

FIG. 8B illustrates a first example implementation of a hall effector sensor in a gap formed in a first plated layer (comprising first magnetic material layer and a first outer conductive layer) of a current transformer that can measure direct current (DC) current, according to an example embodiment.

FIG. 8C illustrates a second example implementation of a hall effector sensor in a gap formed in a transformer core of a current transformer, according to an example embodiment.

FIG. 8D illustrates a current sensor that includes a gap formed partially across the first plated layer (first magnetic material layer/first outer conductive layer) of a current transformer that is capable of measuring alternating current (AC) current and DC current, according to an example embodiment.

FIG. 8E is a diagram depicting an operational flow of the current sensor of FIG. 8D, according to an example embodiment.

FIG. 8F illustrates how the current sensor of FIG. 8D can measure high frequency AC current, according to an example embodiment.

FIG. 9A-9C illustrate techniques to form a gap in a via magnetic structure side wall to minimize eddy currents that can flow in transformer structures, according to an example embodiment.

### DESCRIPTION OF EXAMPLE EMBODIMENTS

### Overview

Presented herein are configurations for micro transformer structures implemented in a PCB allowing for multiple integrated high voltage (400V) to rail step-down transformers in a PCB. These structures can be added in parallel to provide significant amounts of current. These techniques can achieve a 400V step down to an ASIC rail voltage, or to a voltage level as close as possible to the ASIC rail voltage to minimize or eliminate resistive losses in the PCB. The magnetic components are integrated into a PCB, followed by the primary windings, followed by the secondary windings, to deliver high voltage directly to an ASIC with minimal power losses. These transformer structures are suitable for creating inductance, measuring current, or detecting fault currents.

In one embodiment, an apparatus is provided comprising a printed circuit board having a plurality of layers; and a (micro) transformer structure implemented in the plurality of layers of the printed circuit board. The transformer structure comprises a transformer core formed in a hole through the plurality of layers of the printed circuit board; a plurality of transformer primary conductive paths formed through the plurality of layers of the printed circuit board; and a plurality of transformer secondary conductive paths formed through the plurality of layers of the printed circuit board.

In another embodiment, an apparatus is provided comprising a printed circuit board having a plurality of layers; a first transformer monument structure implemented in the plurality of layers of the printed circuit board and a second transformer monument structure in the plurality of layers of the printed circuit board. The first transformer monument structure comprises a transformer core formed in a hole through the plurality of layers of the printed circuit board; and a transformer primary conductive path formed around the transformer core through the plurality of layers of the printed circuit board. The second transformer monument structure comprises a transformer core formed in a hole through the plurality of layers of the printed circuit board; and a transformer secondary conductive path formed around the transformer core through the plurality of layers of the printed circuit board. In addition, a first magnetic material layer is provided that extends on a first outermost layer between the transformer core of the first transformer monument structure and the transformer core of the second transformer monument structure, and a second magnetic material layer that extends on a second outermost layer between the transformer core of the first transformer monument structure and the transformer core of the second transformer monument structure.

Further still, an apparatus is provided comprising a printed circuit board having a plurality of layers; a plurality of transformer cores implemented in the plurality of layers of the printed circuit board; a first plated layer extending on a first outermost layer of the plurality of layers at a first end of the plurality of transformer cores; a second plated layer extending on a second outermost layer of the plurality of layers at a second end of the plurality of transformer cores; and an inner conductive layer formed in one or more of the plurality of layers of the printed circuit board between rows of the plurality of transformer cores, and between the first plated layer and the second plated layer, the inner conductive layer configured to receive a current to flow therethrough and for which a measurement is to be made.

### Example Embodiments

System power efficiencies have improved over the recent decade. For example, in a system that includes a power shelf and a line card or fabric card, power efficiency from input power to the power shelf to the line card or fabric card was approximately 77% some 10-15 years ago. More recently, system power efficiency has improved to 87%, and in both of these examples, the voltage level provided by the power shelf to the line card or fabric card is 54 Volts (V). With Application Specific Integrated Circuit (ASIC) rail voltages getting lower, power getting higher, the current is even greater. Thus, in some present data networking/computing systems, 54V provided as the input power to a line card or fabric card is no longer a suitable starting voltage. There is a movement in some technologies to shift to a substantially higher voltage, such as 400V direct current (DC). However, doing this creates challenges in converting from 400V to 1V or to 0.6 V in one convenient conversion step.

Presented herein are configurations to use micro magnetics approaches to do a step-down voltage conversion from a high voltage (e.g., 400 V) to a very low voltage (e.g., 1V or 0.6 V). These techniques can be employed in a Registered Jack (RJ) 45 Power-over-Ethernet (POE) ethernet ports to remove the need for bulky magnetic components. While the underlying approach presented herein involves features in the so-called outer layers of a printed circuit board, these features can be easily implemented/buried in internal layers of a printed circuit board.

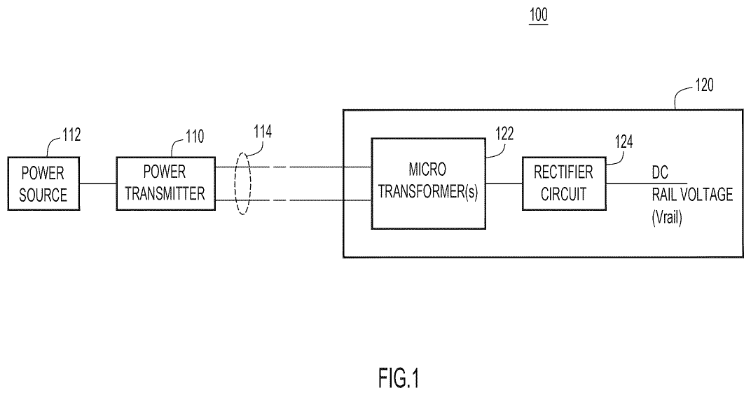

To this end, reference is now made to FIG. 1. FIG. 1 illustrates a high-level block diagram of a power delivery apparatus 100 that is configured to transmit a power waveform to a rail voltage converter that converts the power waveform to a rail voltage for use by one or more power consuming devices, such as an integrated circuit. The power delivery apparatus 100 includes a power transmitter 110 configured to connect to a rail voltage converter 120. A power source 112 provides alternating current (AC) or direct current (DC) input power to the power transmitter 110. The power transmitter 110 is connected to the rail voltage converter 120 by a wire pair 114, and generates a power waveform at a first voltage. The power waveform may comprise a series or sequence of successive on-times that are separated by an off-time. The power waveform may be a periodic waveform having a rectangular or other shape.

The rail voltage converter 120 includes a one or more micro transformers 122 and a rectifier circuit 124. The one or more micro transformers 122 are configured to receive the power waveform from the power transmitter 110 via the wire pair 114 and perform a single step-down conversion of the power waveform at the first voltage to an output waveform at a second voltage. The rectifier circuit 124 is coupled to the transformer 122 to receive the output waveform and produce a DC rail voltage (Vrail) for use by one or more power consuming devices, such as an integrated circuit. As described further below, the one or more micro transformers 122 (and the rectifier circuit 124) of the rail voltage converter 120 may be implemented in a printed circuit board (PCB).

In one example, the power source 112 provides AC or DC input power at 1000 watts (W) after isolation and conversion. The power transmitter 110 produces a high voltage power waveform. In one example, the voltage (the aforementioned “first voltage”) of the high voltage power waveform is in the range of 120V to 500 V. In one example, the high voltage power waveform is 380 or 400 VDC. The one or more micro transformers 122 of the rail voltage converter 120 in a single-step, transform the high voltage power waveform to a much lower voltage output waveform (at a second voltage). The rectifier circuit 124 converts the output waveform from the transformer 122 to a DC rail voltage. For example, the DC rail voltage may be in the range of 0.5 V to 1.6 V, at 100 A to 500 A, for example. The length of the wire pair 114 between the power transmitter 110 and the rail voltage converter 120 may vary, but may be up to one meter (m).

Embodiments are presented herein for a micro transformer (one or more instances of which are included in a rail voltage converter) to generate rail voltage power for delivery to the pads of an ASIC, as an example. The structure of the micro transformer uses a plating arrangement similar to that used for meta conductors. In meta conductors, ferric based magnetic properties are plated into/onto copper already in the copper wire. The embodiments presented herein enable creating the correct ferric structure for incorporation into a PCB.

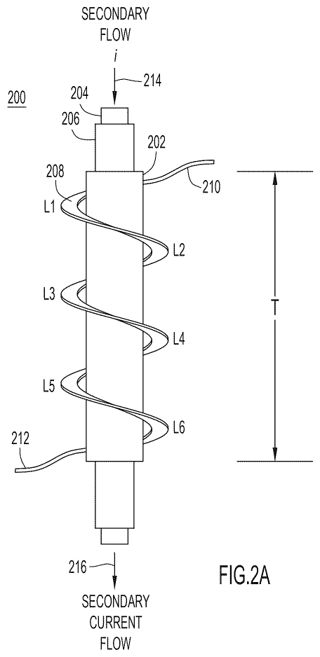

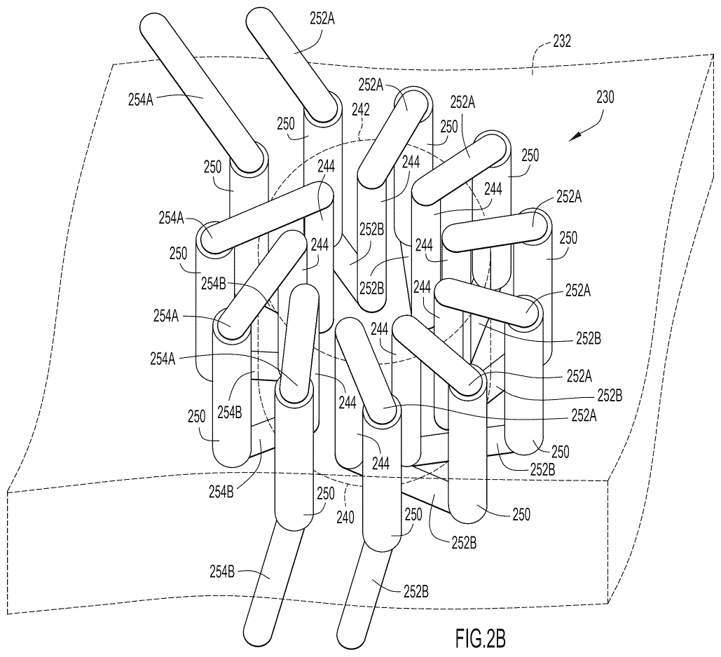

Reference is now made to FIG. 2A. FIG. 2A shows a cross-sectional view of a micro transformer structure 200 for incorporation into a PCB. The micro transformer structure 200 is built around a transformer core 202 that comprises a copper barrel that is plated for a magnetic material layer (comprising one or more layers of iron, nickel, and silver) to create a ferro-magnetic (transformer) core. A copper wire 204 is provided for the transformer core 202 to form a transformer secondary winding. The copper wire 204 may be surrounded by insulation 206. There are copper paths in layers L1, L2, L3, L4, L5 and L6 that form a wire 208 that is wrapped around the transformer core 202 to server as the transformer primary winding. Primary current flow, such as a 400 V square wave, may be applied to the transformer primary winding as shown at reference numeral 210, and the primary current flow return is shown at 212. Secondary current flow is shown at reference numerals 214 and 216. The thickness T of the transformer core 202 may be quite small, such as 0.095 mils, where mils refers to 0.001 inch. This micro transformer structure 200 can achieve voltage transformation without cross talk. The secondary current flow is at a rail voltage (Vrail), e.g., 0.6 V.

FIG. 2B illustrates a three-dimensional view of a micro transformer structure 230 formed in a PCB 232, according to another example embodiment. The micro transformer structure 230 includes a transformer core 240 formed by drilling a central hole (e.g., of 50 mils diameter) through a PCB and the circular wall of the hole is plated with magnetic material (one or more layers of iron and nickel, for example). The space 242 inside the hole of the transformer core 240 may be filled with a non-conductive resin or other similar material. A plurality of relatively small holes 244 (e.g., 6 mils diameter) are drilled through the non-conductive resin after the resin is cured. The walls of the holes 244 are plated with conductive material, e.g., copper.

A plurality of holes 250 (e.g., 9 mils in diameter) are drilled through the PCB around the hole of the transformer core 240. The walls of the holes 250 are plated with copper. In addition, the top exposed areas of the holes are plated to form pad connections.

A first subset of the holes 250 are dedicated to transformer primary conductive paths and transformer primary inputs 252A and transformer primary outputs 252B are connected to the first subset of the holes 250. Similarly, a second subset of the holes are dedicated to transformer secondary conductive paths and transformer secondary inputs 254A and transformer secondary outputs 254B are connected to the second subset of the holes 250.

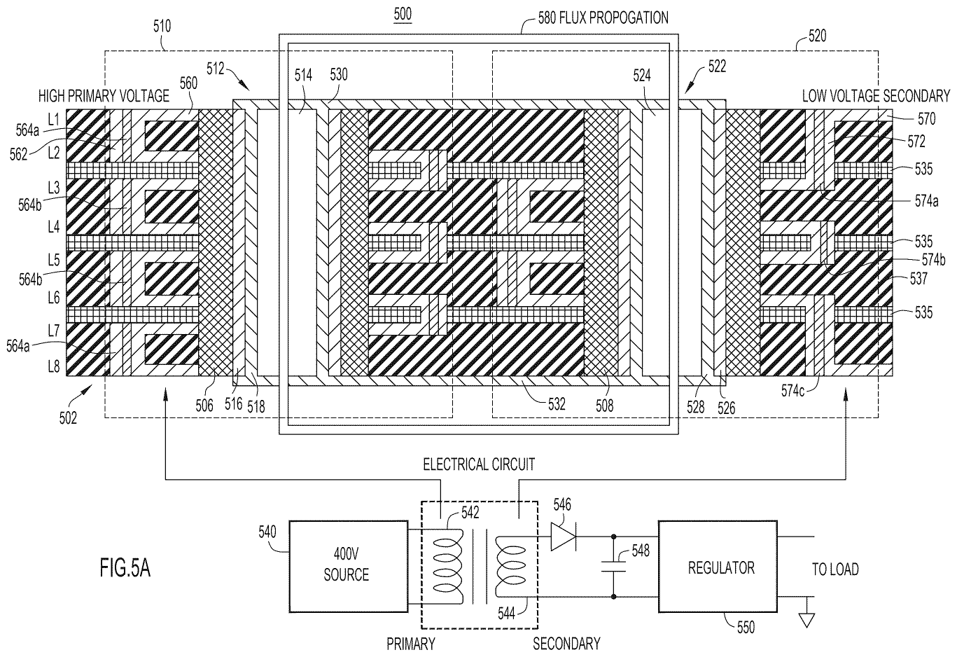

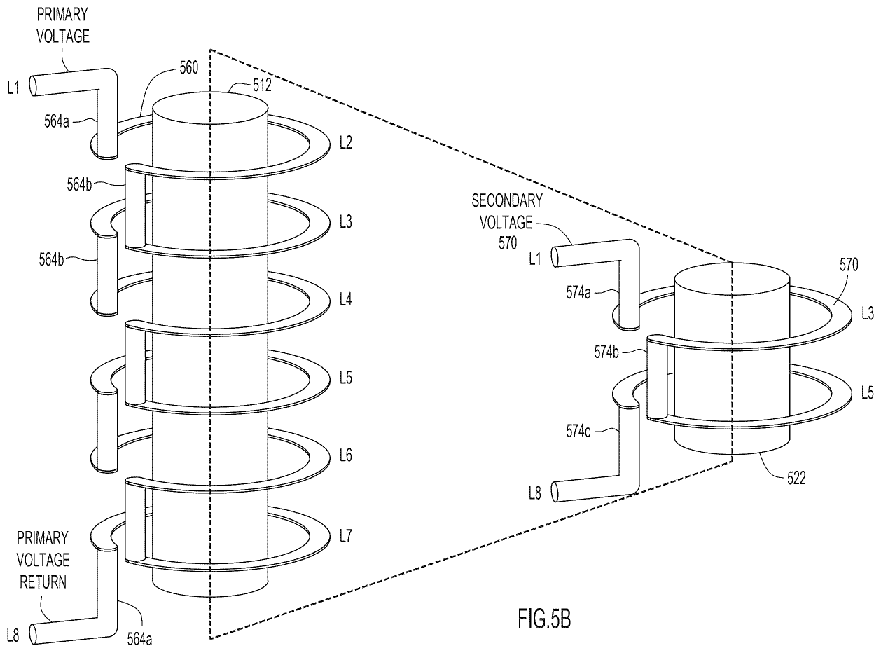

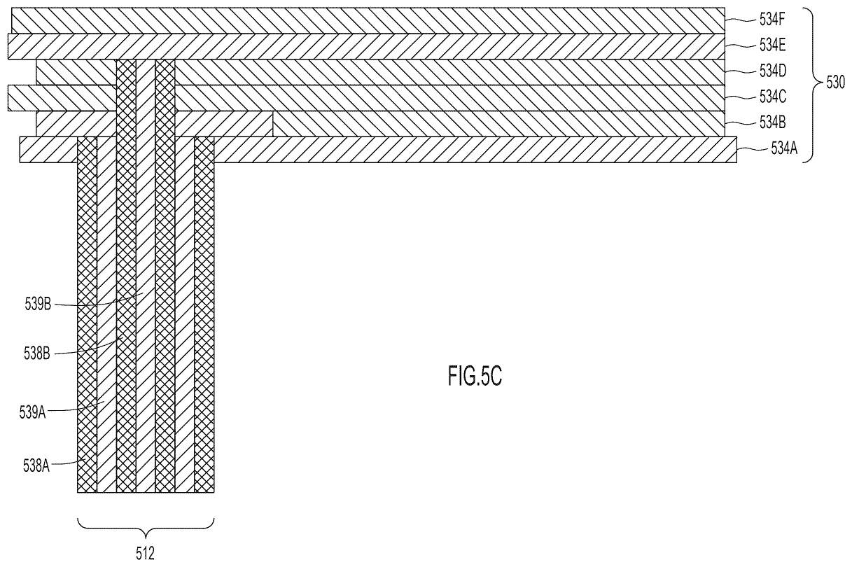

The micro transformer structure 230 is useful to achieve a desirable flux flow direction between two (or more) transformer monuments in a micro transformer implemented in a PCB, such as that shown in FIGS. 5A and 5B described below. Moreover, the micro transformer structure 230 may be used in any of the embodiments presented herein.

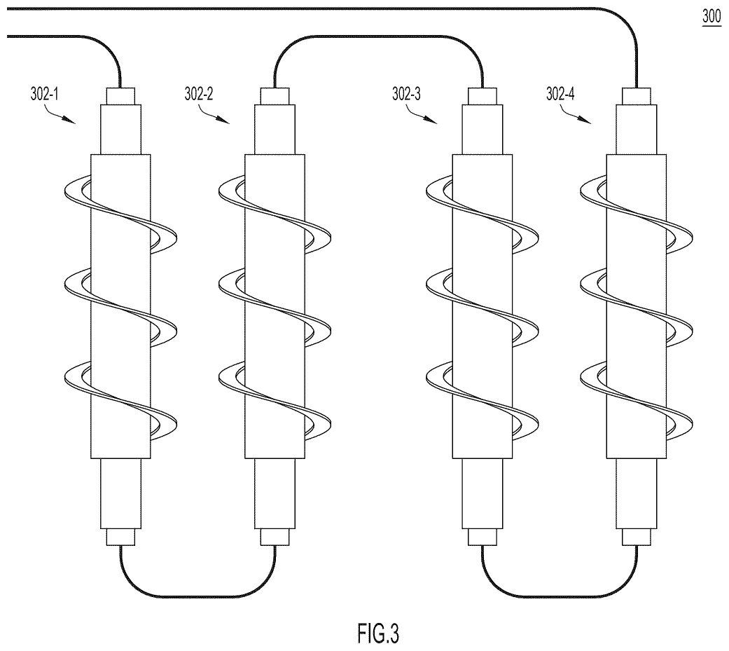

FIG. 3 shows an arrangement 300 with multiple micro transformers 302-1, 302-2, 302-3 and 302-4 (having a structure of the micro transformer structure shown in FIG. 2A) connected in series with each other to increase the overall inductance (a summation of the inductance of each micro transformer). Moreover, it is possible to connect the micro transformers in parallel as well.

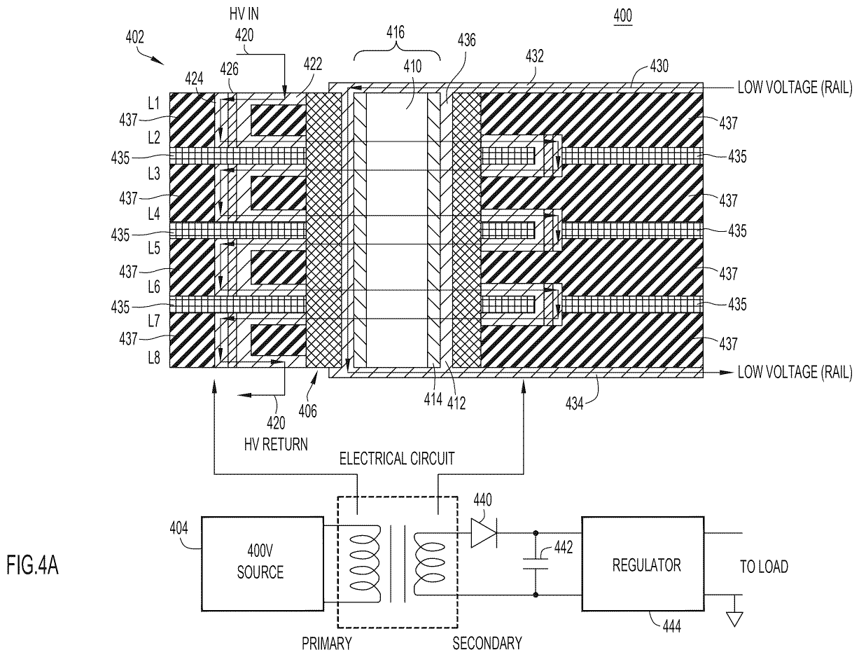

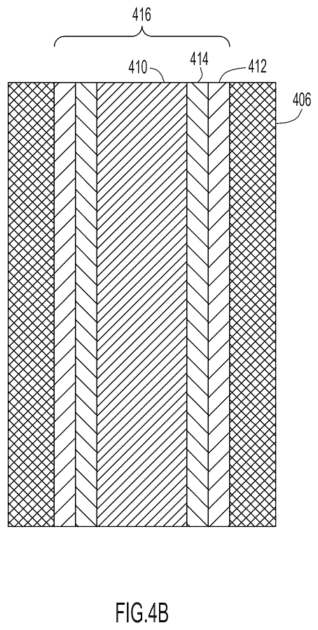

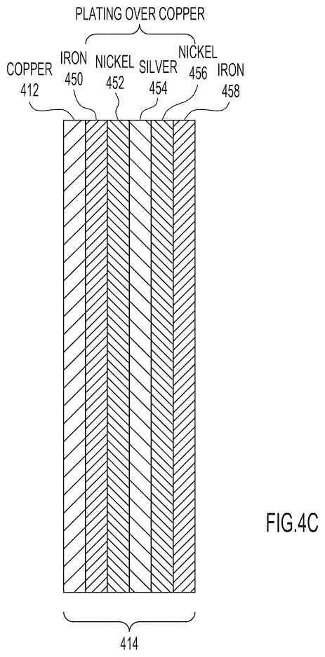

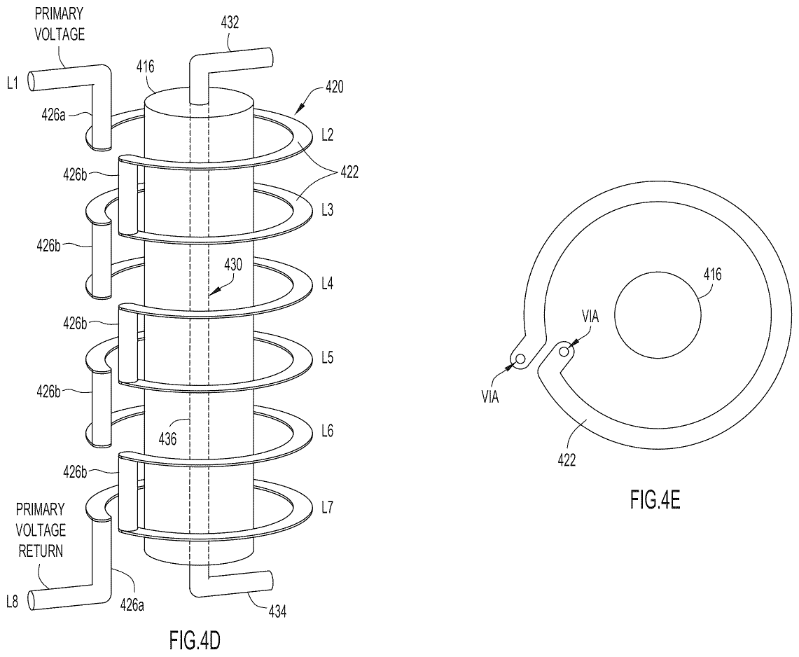

Turning now to FIG. 4A, a fully integrated PCB micro-magnetic step down transformer 400 is shown in a cross-sectional view of layers of a PCB 402, according to an example embodiment. The layers of the PCB 402 are enumerated L1-L8, but it should be understood that there could be many more or fewer layers in a given implementation. A 400V source 404 shown at the bottom of FIG. 4A could be Alternating Current (AC), pulsed Direct Current (DC), fault managed power voltage or fault managed power current, where fault managed power implies that there is fault detection performed at the power source to shut down power when a fault is detected.

The transformer 400 may be implemented in the PCB 402 as follows. A hole 406 is drilled through the layers L1-L8 of the PCB 402 and filled with an insulating material. A hole 410 is drilled through the layers L1-L8 of the PCB 402. The hole 410 is for creating a transformer core. An internal wall of the hole 410 is plated with a conductive layer 412, such as with copper, and the conductive layer 412 is plated with a magnetic material layer 414. Thus, the magnetic material layer 414 surrounds an internal empty space of the hole 410. This forms a transformer core 416. The transformer core 416 may be circular in cross-section.

A transformer primary conductive path 420 is formed by first conductive portions 422 that extend within the plurality of layers and circumscribe the transformer core, 416 and second conductive portions 424 that extend through the PCB 402 and circumscribe a blind/buried via 426 between the first conductive portions 422 in adjacent layers of the plurality of layers L1-L8.

A transformer secondary conductive path 430 is formed by a first conductive portion 432 within a first outermost layer (layer L1) of the plurality of layers that is at a first end of the transformer core 416 and circumscribing the transformer core 416, a second conductive portion 434 within a second outermost layer (layer L8) of the plurality of the printed circuit board that is at a second end of the transformer core 416 and circumscribing the transformer core 416, and a third conductive portion 436 extending through the plurality of layers between the first outermost layer (L1) and the second outermost layer (L8) circumscribing the transformer core 416 and electrically connecting the first conductive portion 432 and the second conductive portion 434 of the transformer secondary conductive path 430.

The PCB 402 is shown with 8 layers, in this example. Layers L2 and L3 are created with a copper over copper layer built on each side of a PCB core material 435. The core material 435 may be made of a glass weave and resin material. Layers L4/L5 and L6/L7 are also made of copper layers on core material. The inner layer sets (L2/L3, L4/L5, and L6/L7), are then assembled with B-stage PCB material 437 to fill between them. Layers L1 and L8 are sheets of copper added over the B-stage material 437. B-stage material is also referred to as “prepreg,” and is a sheet material that consists of a reinforcing material, such as fiberglass, impregnated with a resin that has been cured to an intermediate stage, known as B-stage resin. This resin is partially cured, allowing it to hold the reinforcing material together while still maintaining a certain level of malleability. B-Stage material provides mechanical strength and insulation properties to a PCB. This is useful in the creation of multilayer PCBs. During the PCB lamination process, the B-stage material is subjected to heat and pressure, which fully cures the resin and bonds the layers together, resulting in a solid and rigid PCB.

The electrical circuit representation of the transformer 400 is shown at the bottom of FIG. 4A. In one use case, the current of the secondary is coupled through a rectifying arrangement consisting of a diode 440 and capacitor 442 to a regulator 444, which in turn connects to a load (not shown).

Reference is now made to FIGS. 4B and 4C. FIG. 4B illustrates the transformer core 416 in a PCB in more detail. Again, the transformer core comprises a tubular space and the wall of the tubular space comprises the conductive layer 412 and the magnetics material layer 414 plated over the conductive layer 412. In one example, the conductive layer 412 is copper that is plated over the PCB wall inside the tubular space.

FIG. 4C illustrates an example of the magnetic material layer 414 in more detail, according to an example embodiment. In one example, the magnetic material layer 414 may consist of a first layer 450 of iron (Fe), a second layer 452 of nickel (Ni), a third layer 454 of silver (Ag), a fourth layer 456 of nickel and a fifth layer 458 of iron. The layers 450-458 are plated over each other after the first layer 450 is plated over the conductive layer 412. In one example, the magnetic material layer 414 comprises the first layer 450 of iron and one or more of the second layer 452 of nickel (Ni), the third layer 454 of silver (Ag), and the fourth layer 456 of nickel.

FIGS. 4D and 4E illustrate the elements of the transformer 400 in different views. FIG. 4D shows an isolated view of the conductive elements (copper layer loops) that wind around the transformer core 416. In particular, FIG. 4D illustrates the transformer primary conductive path 420 with the first conductive portions 422 within the layers L1-L8 and that wind around the transformer core 416 in those layers, and second conductive portions (not visible in FIG. 4D) that extend through a blind via 426a and buried vias 426b between adjacent layers. The transformer secondary conductive path 430 comprises first conductive portion 432 within a first outermost layer (layer L1), second conductive portion 434 within a second outermost layer (layer L8), and a third conductive portion 436. The top (“birds eye” (view) of FIG. 4E shows the first conductive portions 422 that wrap around the transformer core 416.

Using the techniques described above in connection with FIGS. 4A-4E, a multiple monument transformer 500 may be created that is fully integrated into a PCB 502, as shown in FIG. 5A. Specifically, the multiple monument transformer 500 comprises a first transformer monument structure 510 that includes a transformer core 512 and a second transformer monument structure 520 that includes a transformer core 522. There is hole 506 drilled through the PCB 502 for the first transformer monument structure 510 and a hole 508 drilled through the PCB 502 for the second transformer monument structure 520. The first transformer monument structure 510 and the second transformer monument structure 520 have a similar structure that is slightly different from that shown in FIGS. 4A-4E as described below. In addition, there is a first magnetic material plated layer 530 (also called a top plated member) across layer L1 between the magnetic material layers of the transformer cores 512 and 522 of the first and second transformer monument structures 510 and 520. Similarly, there is a second magnetic material plated layer 532 (also called a bottom plated member) across layer L8 between the magnetic material layers of the transformer cores 512 and 522 of the first and second transformer monument structures 510 and 520. The first and second magnetic material plated layers 530 and 532 may be formed of plated layers of nickel, iron and silver, in one example. There is a core material 535 and B-stage material 537 between layers of the PCB 502, similar to that shown in FIG. 4A.

As shown in FIG. 5A, an electrical circuit representation is shown of the multiple (two) monument transformer 500 in a PCB 502, in which a high voltage source (e.g., 400 V) 540 is coupled to a transformer primary 542, and the transformer secondary 544 is coupled to a rectifying diode 546 and capacitor 548, which is in turn couple to a regulator 550 to be connected to a load. The first transformer monument structure 510 serves as the transformer primary 542 and the second transformer monument structure 520 serves as the transformer secondary 544.

Similar to the transformer structure shown in FIGS. 4A-4E, the transformer core 512 of the first transformer monument structure 510 includes a hole 514 that is plated with a conductive layer 516, such as with copper, and the conductive layer 516 is plated with a magnetic material layer 518. Thus, the magnetic material layer 518 surrounds an internal empty space of the hole 514.

The first transformer monument structure 510 further includes a transformer primary conductive path formed by first conductive portions 560 that extend within the plurality of layers and circumscribe the transformer core 512 and second conductive portions 562 that extend through the PCB 502 and circumscribe a blind vias 564a and buried vias 564b between the first conductive portions 560 in adjacent layers of the plurality of layers L1-L8.

The transformer core 522 of the second transformer structure 520 includes a hole 524 that is plated with a conductive layer 526, such as with copper, and the conductive layer 526 is plated with a magnetic material layer 528. Thus, the magnetic material layer 528 surrounds an internal empty space of the hole 524.

The second transformer monument structure 520 further includes a transformer secondary conductive path formed by first conductive portions 570 that extend within the plurality of layers and circumscribe the transformer core 522 and second conductive portions 572 that extend through the PCB 502 and circumscribe blind/buried vias 574a, 574b and 574c between the first conductive portions 570. More specifically, the blind via 574a enables the second conductive portion 572 to make an electrical connection between the first conductive portion 570 in layer L1 with the first conductive portion 570 in layer L3. The buried via 574b enables the second conductive portion 572 to make an electrical connection between the first conductive portion 570 in layer L4 with first conductive portion 570 in layer L5. The blind via 574c enables the second conductive portion 572 to make an electrical connection between the first conductive portion 570 in layer L6 with the first conductive portion 570 in layer L8.

FIG. 5A shows at 580 the magnetic flux propagation from the second transformer structure 520 (serving as the transformer secondary) to the first transformer structure 510 (serving as the transformer primary). It is noted that FIG. 5A shows a two monument micro transformer structure, but it is also possible to use these techniques to build a 3, 4, or more monument transformer structure.

Reference is now made to FIG. 5B, which shows the conductive loops around the magnetic cores to form a full magnetic loop. FIG. 5B further shows the magnetic flux flow 580 between the transformer secondary formed by the transformer core 522 and associated windings and the transformer primary formed by the transformer core 512 and associated windings.

FIG. 5C illustrates a cross-sectional view of a structure that may be used in more detail, the first magnetic material plate layer 530 (i.e., the top plate member), as well as an example structure of a transformer core, e.g., transformer core 512. For simplicity, only the top plate member is shown interconnected with a transformer core, but it should be understood that the structure shown in FIG. 5C may be used for the bottom plate member.

The first magnetic material plate layer 530 (the top plate member) may be formed from a copper layer 534A that is plated over with two layers 534B and 534C of iron. A hollowed-out layer 534D may be filled with glass and resin, followed by a layer 534E of copper that is plated by a layer 534F of iron.

The transformer core 512 is formed by drilling a relatively larger hole 538A in the PCB (e.g., 30 mils) and a relatively smaller hole 538B. The larger hole is plated with a layer 539A of conductive material (e.g., copper), and the smaller hole 538B, which normally may be left hollow, is plated with a layer 539B of conductive material (e.g., copper) that extends through to bond above the layer 534D to layer 534E as well to bond to layers beneath layer 534D.

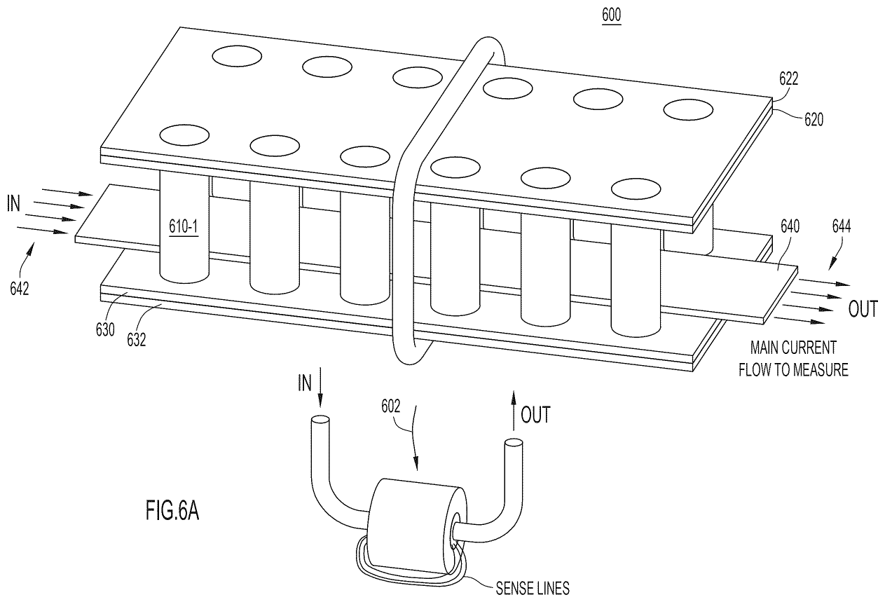

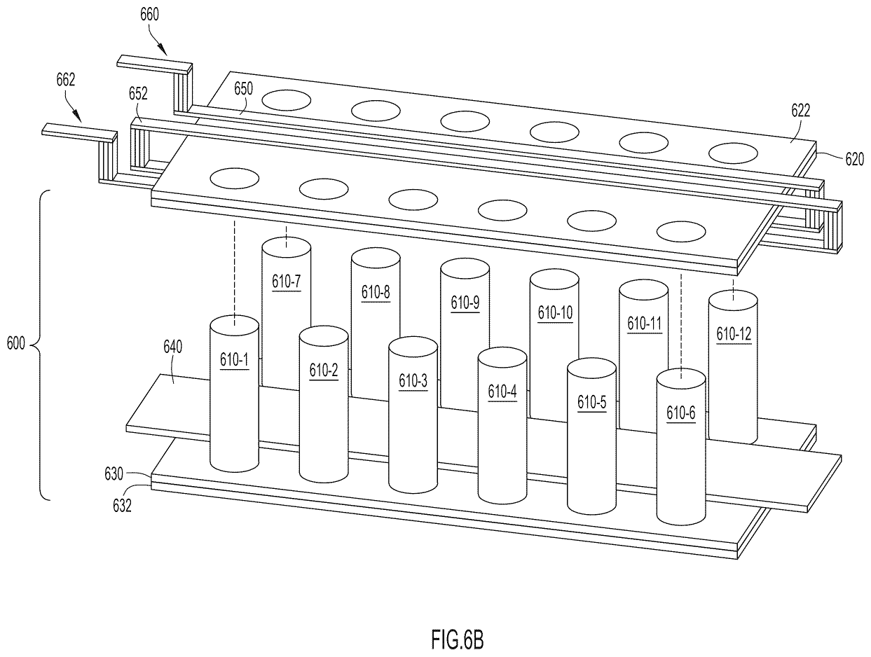

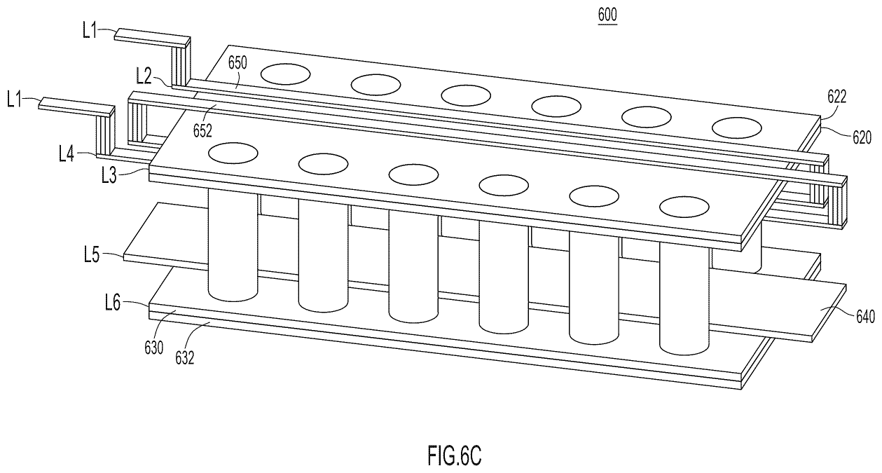

Reference is now made to FIGS. 6A, 6B and 6C. These figures illustrate a current transformer 600 built from a plurality of transformer structures implemented in a plurality of layers of a PCB. The current transformer 600 may be configured to mimic a toroid-based current transformer 602, as shown in FIG. 6A. The current transformer 600 includes a plurality of transformer cores 610-1 to 610-N arranged in rows (e.g., first and second rows), with each transformer spaced from each other in a given row and between rows. There is a first magnetic material layer 620 extending on a first outermost layer (L1) on one side of the plurality of transformer cores 610-1 to 610-N, and a second magnetic material layer 630 extending on a second outermost layer (L6) on another side of the plurality of transformer cores 610-1 to 610-N. A first outer conductive layer 622 is formed on the first magnetic material layer 620, and a second outer conductive layer 632 is formed on the second magnetic material layer 630. An inner conductive layer 640 is formed in one or more of the plurality of layers of the printed circuit board between the first and second rows of transformer cores 610-1 to 610-N, and also between the first magnetic material layer 620 and the second magnetic material layer 630. The conductive layers 622, 632 and 640 may be formed of copper plating. The magnetic material layers 620 and 630 may be formed of one or more layers of iron, nickel and silver, in one example. The current to be measured is applied at one end 642 of the inner conductive layer 640 and is output at the other end 644 of the inner conductive layer 640.

As best shown in the exploded view of FIG. 6B, when N=12, there are a plurality of transformer cores 610-1-610-12, where a first row consists of transformer cores 610-1, 610-2, 610-3, 610-4, 610-5 and 610-6, and a second row consists of transformer cores 610-7, 610-8, 610-9, 610-10, 610-11 and 610-12. Each of the transformer cores 610-1 to 610-12 may have a structure similar to that shown for the transformer core in FIGS. 4A-4E, that is, a conductive layer onto which a magnetic material layer is plated.

There are current sense lines 650 and 652 that extend on top of the conductive layer 622 and around and along the bottom of the first magnetic material layer 620, with associated sense outputs 660 and 662. The current sense lines 650 and 652 are provided to measure the current through the inner conductive layer 640. FIG. 6C shows the current transformer 600 formed in six layers, L1-L6, of a PCB, as an example. Thus, the current transformer 600 may be used for AC current measuring/monitoring.

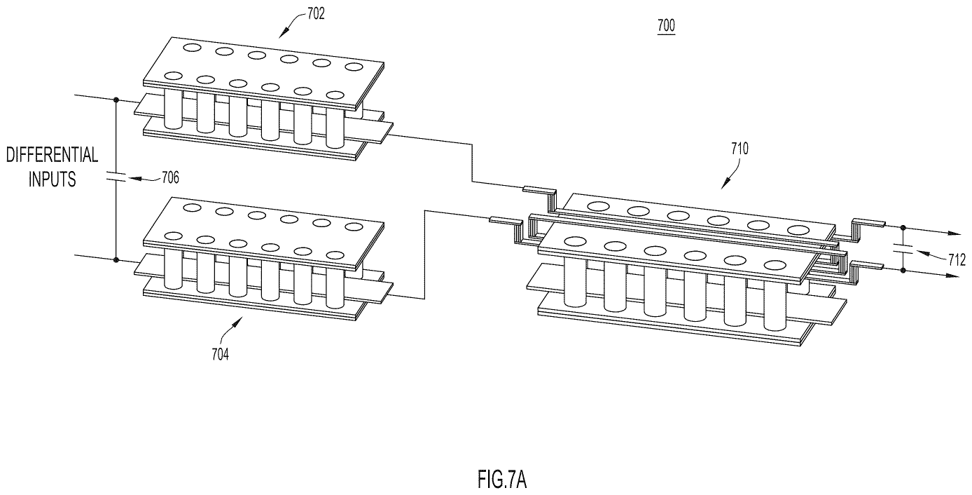

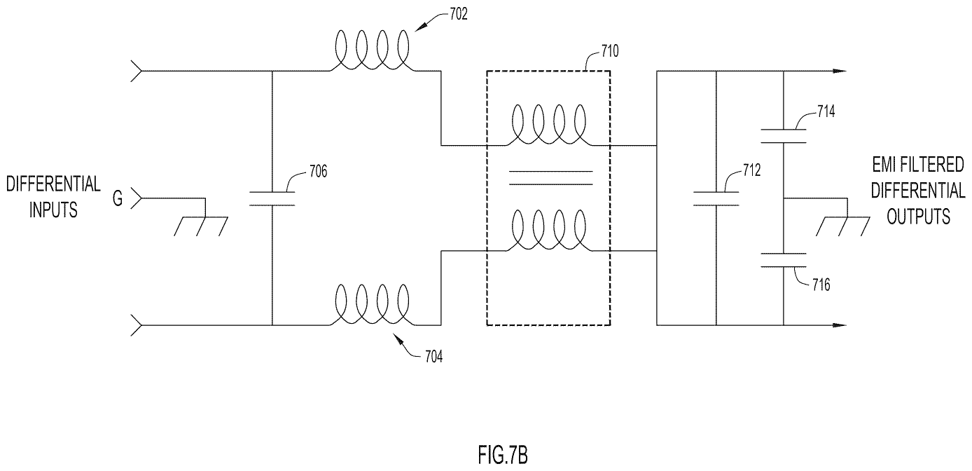

FIGS. 7A and 7B illustrate an electromagnetic interference (EMI) filter 700 as one example use case of the current transformer 600 shown FIGS. 6A-6C. The EMI filter 700 is useful to limit conducted emissions. FIG. 7B is a schematic representation of the EMI filter 700. The EMI filter 700 comprises a first current transformer 702 and a second current transformer 704 each to serve as single inductors in the schematic representation of FIG. 7B. A capacitor 706 is coupled across the inputs to the first and second current transformers 702 and 704. The first and second current transformers are followed, in series, by a current transformer 710 configured with mutually coupled inductors. The magnetic cores in the current transformer structure (of FIGS. 6A-6C) are used to create inductors and to create mutual inductors. A capacitor 712 is connected across the outputs of the current transformer 710, and there are capacitors 714 and 716 connected with respect to ground from each of the outputs of the current transformer 710. Differential current signals are provided as inputs to the EMI filter at the first and second current transformers 702 and 704 and the EMI filter generates EMI filtered differential current signals at the outputs of the current transformer 710.

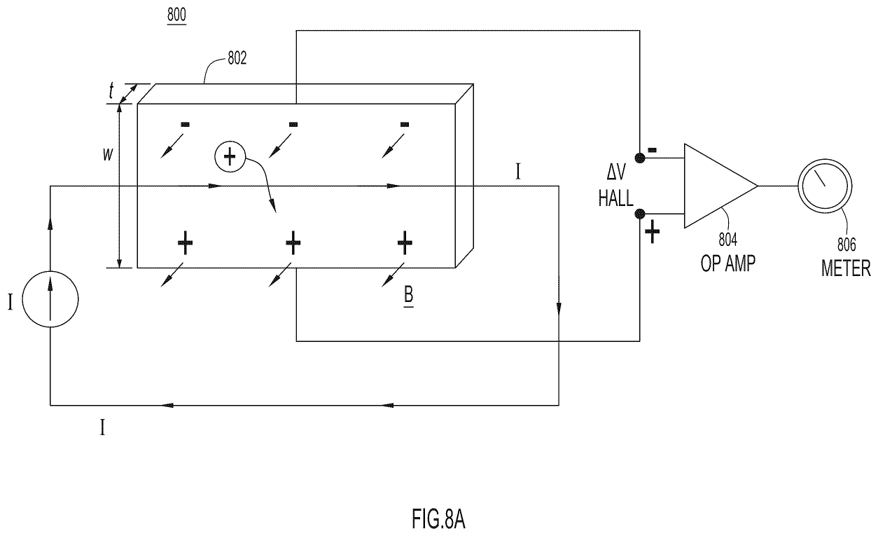

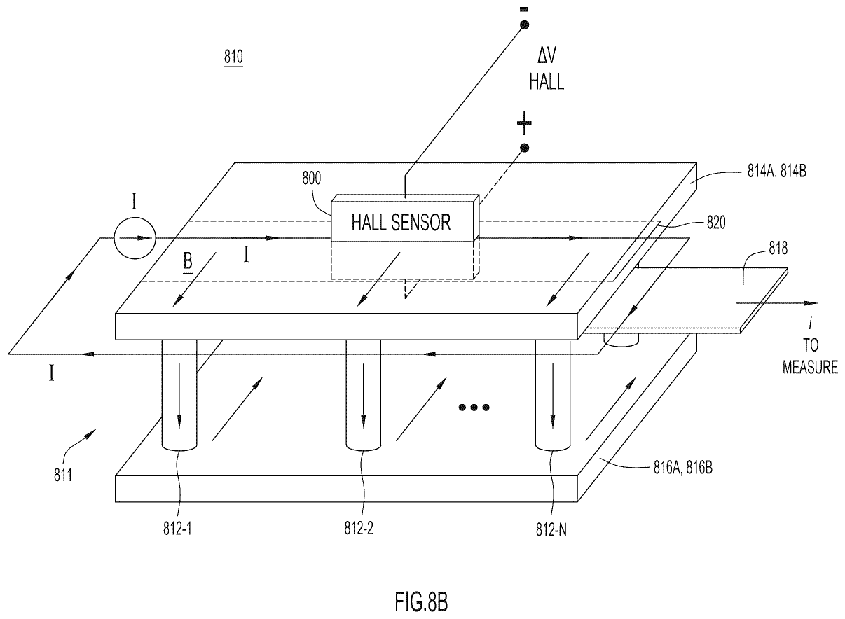

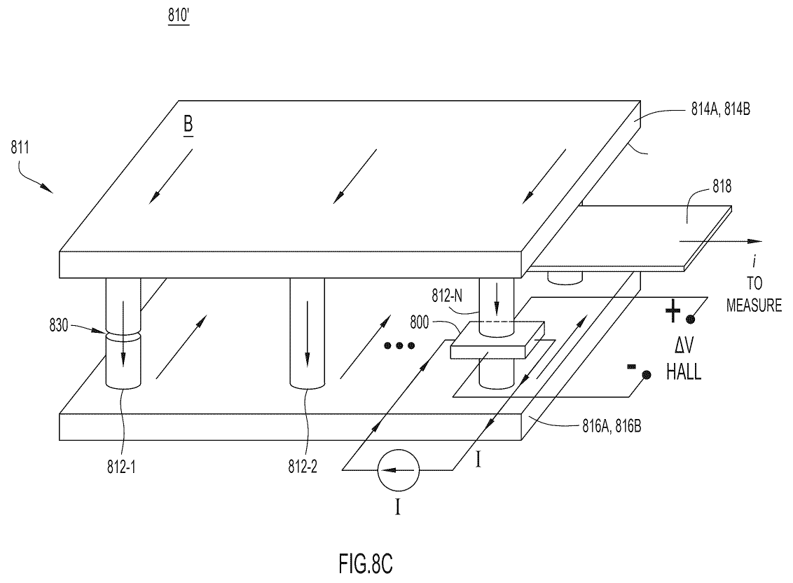

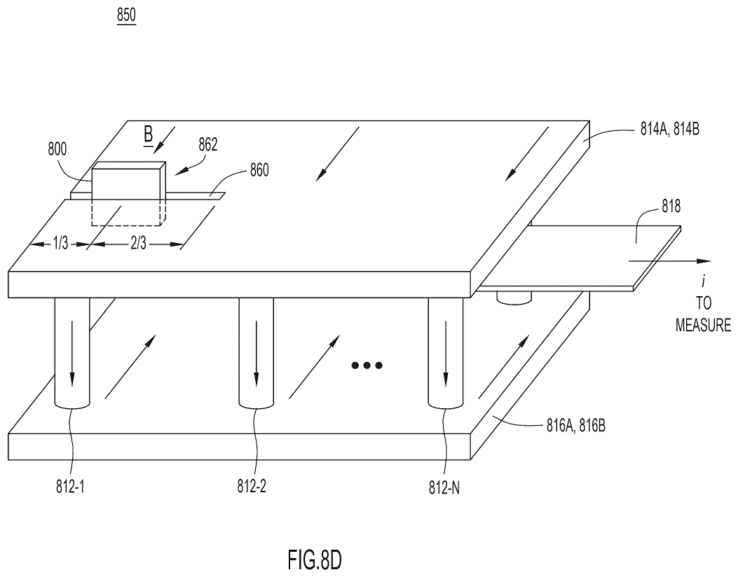

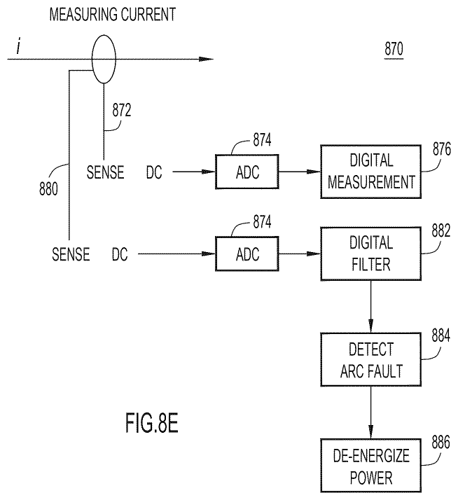

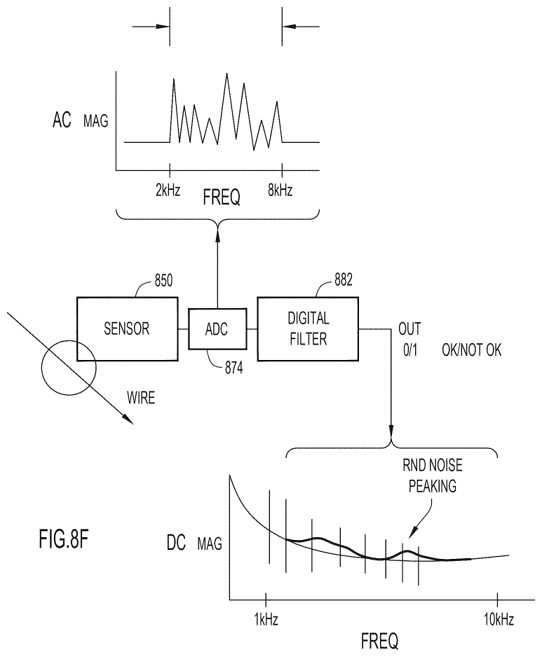

As described above, the current transformer arrangement depicted in FIGS. 6A-6C is suitable for measuring/monitoring an AC current waveform. With reference to FIGS. 8A-8F, embodiments are now described for a current transformer arrangement that can serve as a current sensor for DC current. FIG. 8A shows a schematic diagram of a hall effect sensor 800 that, as described further below, may be used to augment the current transformer arrangement described herein to support DC current sensing capabilities. The hall effect sensor 800 includes a P-type semiconductor 802 having a thickness t and a width w. Current, i, to be measured, produces a magnetic field in the p-type semiconductor 802, and a voltage across the width w is generated as a result. This voltage is denoted as “AV Hall”. The AV Hall voltage is applied to an operational amplifier 804 and then to a meter 806 to obtain a measurement of the current i flowing in the copper trace through the transformer structure.

Turning now to FIGS. 8B, 8C and 8D, various embodiments are shown for ways to integrate the hall effect sensor 800 into the current transformer arrangement to provide DC current sensing. FIG. 8B illustrates a DC current sensor 810 having the current transformer arrangement of FIGS. 6A-6C a plurality of transformer cores 812-1, 812-2, . . . , 812-N, a first magnetic material layer overlaid by a first outer conductive layer, denoted 814A, 814B and also referred to as a first plated layer, extending on a first outermost layer of PCB 811 on one side/end of the plurality of transformer cores 812-1 to 812-N, and a second magnetic material layer overlaid by a second outer conductive layer, denoted 816A,816B and also referred to as a second plated layer, extending on a second outermost layer of PCB on another side/end of the plurality of transformer cores 812-1 to 812-N. There is an inner conductive layer 818 formed in one or more of the plurality of layers of the PCB between the first and second rows of transformer cores 812-1 to 812-N, and also between the first magnetic material layer/first outer conductive layer 814A, 814B and the second magnetic material layer/second outer conductive layer 816A, 816B. The hall effect sensor 800 is implemented in a gap 820 formed one or more layers of the PCB 811. The gap 820 in the PCB 811 may be formed with a mask in the PCB fabrication process. FIG. 8B shows that the gap 820 is in the first magnetic material layer/first outer conductive material layer 814A,814B as one example (and across an entire width thereof), but it could also be formed in the second magnetic material layer/second outer conductive layer 816A, 816B. The AV Hall voltage generated by the hall sensor 800 is obtained and provided to an operational amplifier and a meter device, as described above in connection with FIG. 8A. Thus, a measure of DC current flowing through the inner conductive layer 818 may be obtained through operation of the hall effect sensor 800 integrated into the PCB.

FIG. 8C shows a different placement of the hall effect sensor 800 in a DC current sensor 810′. Specifically, a gap 830 is created (cut) in one of the transformer cores (and across an entire width of the transformer core), as shown at reference numeral 830. In this example, a gap is created in transformer core 812-N and the hall effect sensor 800 is integrated through the gap of transformer core 812-N. The hall effect sensor 800 generates a AV Hall voltage that is provided to an operational amplifier and meter to obtain a measurement of DC current flowing through the inner conductive layer 818.

FIG. 8D illustrates a sensor 850 employing a current transformer and integrated hall effect sensor arrangement that can measure AC current and DC current. The sensor 850 has a similar current transformer structure as that shown in FIGS. 8B and 8C, but a partial gap 860 is formed, for example, in the first magnetic material layer/first outer conductive layer 814A, 814B, and hall effect sensor 800 is placed at a particular location 862 in the partial gap 860. That is, the partial gap 860 extends partly across the first magnetic material layer/first outer conductive layer 814A, 814B. The location 862 for placing the hall effect sensor 800 is at a strongest field point in the partial gap 860. For example, the location 862 may be at a position corresponding to ⅔ of the length of the partial gap 860 from the right end of the partial gap 860 (or equivalently, at ⅓ of the length from the left end of the partial gap 860), as shown in FIG. 8E.

To summarize, as depicted in FIGS. 8B and 8C, the gap or cut may extend along an entire width of one of the first plated layer (first magnetic material layer/first outer conductive layer 814A, 814B), the second plated layer (second magnetic material layer/second outer conductive layer 816A, 816B) or one of the plurality of transformer cores 812-1 to 812-N. In another arrangement, the gap or cut extends partially along a width one of the first plated layer and the second plated layer. Moreover, the hall effect sensor 800 may be positioned in the gap or cut at a location corresponding to a strongest field point, and the hall effect sensor 800 generates an output that indicates a measurement of an AC current and/or a DC current.

Again, the sensor 850 can measure both AC current and DC current. When measuring DC current, a system level power measurement can be obtained, in real-time. When measuring AC current, the output of the hall effect sensor 800 may be provided to an analog-to-digital (ADC) and a digital filter may be applied to the output of the ADC to look for changes in a particular frequency band, such as an 8 MHz to 25 MHz frequency band. This particular frequency range can show carbon arc faults and if a fault is detected, the system can be de-energized (power-on fault detection).

In FIGS. 8B-8D, the lines labeled B represent field lines of a magnetic field generated by current flowing through the inner conductive layer 818 to be measured.

The mathematical relationships related to the hall effect of the hall effect sensor 800 integrated into the PCB implemented current transformer are as follows. Let/be the constant current that is provided to the semiconductor plate of the hall effect sensor by an external source. At equilibrium, the electrical force F_{EL} and the magnetic force F_{MAG} on the moving charges in the Hall element are equal. In terms of electrical field E and magnetic field B, this equation can be written as eE=evB, where e is the electron charge, and v is the velocity of the charges.

The relation between the Hall voltage ΔV_{HALL} and the magnetic field is then ΔV_{HALL}=wE=wvB, where w is the width of the semiconductor plate. The velocity v of the charges can then be expressed in terms of the current I as

$$v = \frac{I}{γ twe} ,$$

where γ is the density of the charge carriers (holes) in the semiconductor material and t is the thickness of the semiconductor plate. After substituting v in the previous equation, the relation becomes

$${ΔV}_{HALL} = w \frac{I}{γ ywe} B = \frac{IB}{γ te} .$$

Finally, neglecting hysteresis and saturation effects, the magnetic field B is approximately linearly related to the current to measure as B=k·i_{TO MEASURE}, where k is a coefficient that depends on the geometry of the entire micro transformer structure and the permeability of the core. Therefore, the relation between ΔV_{HALL} and i_{TO MEASURE} can be written as

$${ΔV}_{HALL} = \frac{Ik}{γ te} \cdot {i}_{TO MEASURE} ,$$

and because of this, i_{TO MEASURE} can be measured indirectly through ΔV_{HALL}. A measurement instrument can be calibrated to measure ΔV_{HALL} and thus output i_{TO MEASURE}.

Referring now to FIGS. 8E and 8F, an operational flow 870 is now described for the sensor 850, according to an example embodiment. At 872, when DC current is sensed (from the sense lines (FIGS. 6B and 6C)), it is output to an ADC 874 to obtain a digital measurement of the DC current at 876. At 880, when AC current is sensed (from the from the sense lines), the output is provided to the ADC 874, and then applied to a digital filter 882. The output of the digital filter 882 may be analyzed to detect presence of an arc fault, at 884. Specifically, the digital filter 882 may be configured to look for frequency magnitudes in the 8 MHz to 25 MHz range. After subtracting system noise and random noise, the arrangement can detect arc fault conditions. If an arc fault is detected, then at 886, the power to whatever device whose current is being measured, can be de-energized, to prevent failures and injury.

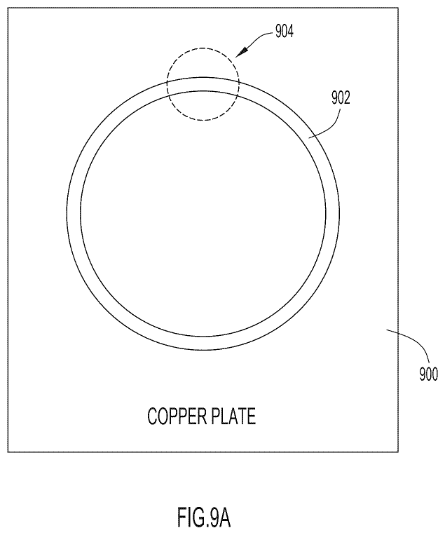

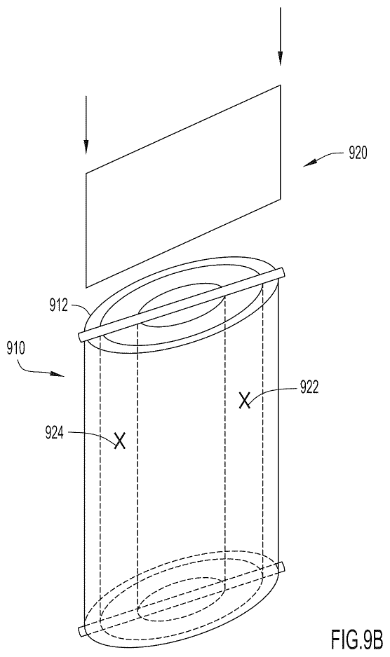

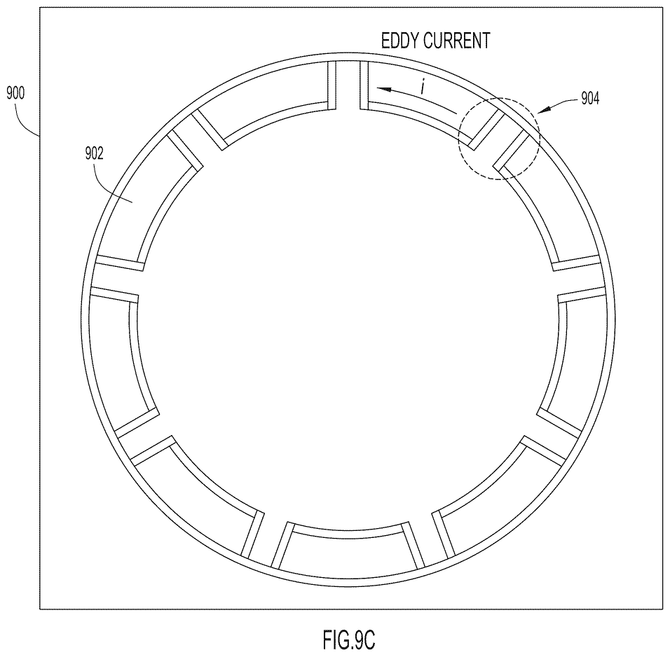

Reference is now made to FIGS. 9A-9C, which illustrate techniques to form a gap in a via magnetic structure side wall to minimize eddy currents that can flow in transformers. Eddy currents can contribute to additional heat and lower efficiency performance.

FIG. 9A illustrates a top view of a copper plate 900. First, a groove 902 is drilled through the copper plate 900. The groove 902 is plated with copper and iron (and optionally one or more other layers of magnetic material) and filled with a nonconductive material. Next, a cut or slot 904 is drilled through the groove 902. The slot or cut may be filled with a non-conductive material or left as an open (air) hole.

FIG. 9B illustrates another technique. A magnetically plated via 910 has been formed through a PCB (not shown). The magnetically plated via 910 has a wall 912 that circumscribes a space. A knife 920 (or other cutting device of extremely small dimensions appropriate for PCB fabrication techniques) is used to cut two grooves 922 and 924 down through the via 910. The grooves 922 and 924 will be 180 degrees separated from each other in the magnetically plated via 910.

The techniques of FIGS. 9A and 9B to create cuts in a via may be used for creating the vias 426 in the transformer 400 of FIGS. 4A-4E, the vias 564a, 564b, 574a, 574b and 574c of the multiple monument transformer 500 of FIGS. 5A and 5B, in vias of the current transformer 600 shown in FIGS. 6A-6C, and in vias of the current sensors of FIGS. 8B-8D.

FIG. 9C illustrates a view from above the copper plate 900 and groove 902 with multiple cuts or slots 904 and various locations around the plated grove 902. As shown in FIG. 9C, the cuts or slots 904 block or greatly reduce the flow of eddy current around the groove 902.

In summary, the micro transformer structures implemented in a PCB allow for multiple integrated 400V to rail step-down transformers in a PCB. These single structures can be added in parallel to provide significant amounts of current. These techniques can achieve a 400V step down to an ASIC rail voltage, or to a voltage level as close as possible to the ASIC rail voltage to minimize or eliminate resistive losses into the PCB. The magnetic components are integrated into a PCB, followed by the primary windings, followed by the secondary windings, to deliver high voltage directly to the ASIC with minimal power losses.

In some aspects, the techniques described herein relate to an apparatus including: a printed circuit board including a plurality of layers; and a transformer structure implemented in the plurality of layers of the printed circuit board, including: a transformer core formed in a hole through the plurality of layers of the printed circuit board; a plurality of transformer primary conductive paths formed through the plurality of layers of the printed circuit board; and a plurality of transformer secondary conductive paths formed through the plurality of layers of the printed circuit board.

In some aspects, the techniques described herein relate to an apparatus, wherein the transformer core includes a conductive layer plated onto an internal wall of the hole and a magnetic material layer plated over the conductive layer and surrounding an internal space of the hole.

In some aspects, the techniques described herein relate to an apparatus, wherein the conductive layer includes copper plating and the magnetic material layer plated over the conductive layer and including a plurality of layers including at least a layer of iron, and one or more layers of nickel and silver.

In some aspects, the techniques described herein relate to an apparatus, wherein the plurality of transformer primary conductive paths extend through the printed circuit board and around a first angular portion of the transformer core and the plurality of transformer secondary conductive paths extend through the printed circuit board and around a second angular portion of the transformer core.

In some aspects, the techniques described herein relate to an apparatus, wherein the plurality of transformer primary conductive paths and the plurality of transformer secondary conductive paths are arranged such that magnetic flux flow is radially orthogonal from the plurality of transformer secondary conductive paths to the plurality of transformer primary conductive paths.

In some aspects, the techniques described herein relate to an apparatus, wherein the transformer core is circular in cross-section.

In some aspects, the techniques described herein relate to an apparatus including: a printed circuit board including a plurality of layers; a first transformer monument structure implemented in the plurality of layers of the printed circuit board and including: a transformer core formed in a hole through the plurality of layers of the printed circuit board; and a transformer primary conductive path formed around the transformer core through the plurality of layers of the printed circuit board; a second transformer monument structure implemented in the plurality of layers of the printed circuit board spaced from the first transformer monument structure, and including: a transformer core formed in a hole through the plurality of layers of the printed circuit board; and a transformer secondary conductive path formed around the transformer core through the plurality of layers of the printed circuit board; and a first magnetic material layer extending on a first outermost layer between the transformer core of the first transformer monument structure and the transformer core of the second transformer monument structure and a second magnetic material layer extending on a second outermost layer between the transformer core of the first transformer monument structure and the transformer core of the second transformer monument structure.

In some aspects, the techniques described herein relate to an apparatus, wherein the transformer core of the first transformer monument structure and the transformer core of the second transformer monument structure includes a conductive layer plated onto an internal wall of the hole and a magnetic material layer plated over the conductive layer.

In some aspects, the techniques described herein relate to an apparatus, wherein the transformer primary conductive path includes a plurality of first conductive portions each of which extends within a corresponding layer of the plurality of layers and circumscribes the transformer core of the first transformer monument structure and second conductive portions that extend in a via through the printed circuit board between first conductive portions in adjacent layers of the plurality of layers of the first transformer monument structure.

In some aspects, the techniques described herein relate to an apparatus, wherein the transformer secondary conductive path includes a plurality of first conductive portions each of which extends within a corresponding layer of the plurality of layers and circumscribes the transformer core of the second transformer monument structure and second conductive portions that extend in a via through the printed circuit board between first conductive portions in adjacent layers of the plurality of layers of the second transformer monument structure.

In some aspects, the techniques described herein relate to an apparatus, wherein the via of the transformer primary conductive path and the via of the transformer secondary conductive path includes at least one cut or slot formed therein.

In some aspects, the techniques described herein relate to an apparatus, wherein the transformer core of each of the first transformer monument structure and the second transformer monument structure includes a conductive layer plated onto an internal wall of the hole and a magnetic material layer plated over the conductive layer and including a plurality of layers including at least a layer of iron, and one or more layers of nickel and silver.

In some aspects, the techniques described herein relate to an apparatus including: a printed circuit board having a plurality of layers; a plurality of transformer cores implemented in the plurality of layers of the printed circuit board; a first plated layer extending on a first outermost layer of the plurality of layers at a first end of the plurality of transformer cores; a second plated layer extending on a second outermost layer of the plurality of layers at a second end of the plurality of transformer cores; and an inner conductive layer formed in one or more of the plurality of layers of the printed circuit board between rows of the plurality of transformer cores, and between the first plated layer and the second plated layer, the inner conductive layer configured to receive a current to flow therethrough and for which a measurement is to be made.

In some aspects, the techniques described herein relate to an apparatus, further including a hall effect sensor integrated into the printed circuit board in a gap formed in one of: a combination of the first plated layer, the second plated layer, or one of the plurality of transformer cores.

In some aspects, the techniques described herein relate to an apparatus, wherein the gap extends along an entire width of: the first plated layer, the second plated layer, or one of the plurality of transformer cores.

In some aspects, the techniques described herein relate to an apparatus, wherein the gap extends partially along a width of one of: the first plated layer, and the second plated layer.

In some aspects, the techniques described herein relate to an apparatus, wherein the hall effect sensor is at a position in the gap at a location corresponding to a strongest field point, and the hall effect sensor generates an output that indicates a measurement of an alternating current (AC) current or a direct current (DC) current.

In some aspects, the techniques described herein relate to an apparatus, further including an analog-to-digital converter configured to receive the output of the hall effect sensor to generate digital values representing the output of the hall effect sensor.

In some aspects, the techniques described herein relate to an apparatus, further including a digital filter configured to analyze the digital values output by the analog-to-digital converter to detect an arc fault.

In some aspects, the techniques described herein relate to an electromagnetic interference filter (EMI) filter including at least a first instance, a second instance 13, wherein the first instance and the second instance of the apparatus are each configured to operate as a single inductor having an input and an output, inputs of the first instance and the second instance configured to receive a differential current signals as input, and outputs of the first instance and the second instance being coupled as input to the third instance of the apparatus, the third instance of the apparatus configured to operate as a mutually coupled inductors, wherein outputs of the third instance of the apparatus include EMI filtered differential current signals.

Note that in this Specification, references to various features (e.g., elements, structures, nodes, modules, components, engines, logic, steps, operations, functions, characteristics, etc.) included in ‘one embodiment’, ‘example embodiment’, ‘an embodiment’, ‘another embodiment’, ‘certain embodiments’, ‘some embodiments’, ‘various embodiments’, ‘other embodiments’, ‘alternative embodiment’, and the like are intended to mean that any such features are included in one or more embodiments of the present disclosure, but may or may not necessarily be combined in the same embodiments. Note also that a module, engine, client, controller, function, logic or the like as used herein in this Specification, can be inclusive of an executable file comprising instructions that can be understood and processed on a server, computer, processor, machine, compute node, combinations thereof, or the like and may further include library modules loaded during execution, object files, system files, hardware logic, software logic, or any other executable modules.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase ‘at least one of’, ‘one or more of’, ‘and/or’, variations thereof, or the like are open-ended expressions that are both conjunctive and disjunctive in operation for any and all possible combination of the associated listed items. For example, each of the expressions ‘at least one of X, Y and Z’, ‘at least one of X, Y or Z’, ‘one or more of X, Y and Z’, ‘one or more of X, Y or Z’ and ‘X, Y and/or Z’ can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Additionally, unless expressly stated to the contrary, the terms ‘first’, ‘second’, ‘third’, etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, ‘first X’ and ‘second X’ are intended to designate two ‘X’ elements that are not necessarily limited by any order, rank, importance, temporal sequence, or hierarchy of the two elements. Further as referred to herein, ‘at least one of’ and ‘one or more of can be represented using the’ (s)′ nomenclature (e.g., one or more element(s)).

Each example embodiment disclosed herein has been included to present one or more different features. However, all disclosed example embodiments are designed to work together as part of a single larger system or method. This disclosure explicitly envisions compound embodiments that combine multiple previously discussed features in different example embodiments into a single system or method.

One or more advantages described herein are not meant to suggest that any one of the embodiments described herein necessarily provides all of the described advantages or that all the embodiments of the present disclosure necessarily provide any one of the described advantages. Numerous other changes, substitutions, variations, alterations, and/or modifications may be ascertained to one skilled in the art and it is intended that the present disclosure encompass all such changes, substitutions, variations, alterations, and/or modifications as falling within the scope of the appended claims.

Further, the present disclosure may repeat reference numerals and/or letters in the various examples. This repetition is for the purpose of simplicity and clarity and does not in itself dictate a relationship between the various embodiments and/or configurations discussed. Example embodiments that may be used to implement the features and functionality of this disclosure are described with more particular reference to the accompanying figures above.

Similarly, when used herein, the term “comprises” and its derivations (such as “comprising”, etc.) should not be understood in an excluding sense, that is, these terms should not be interpreted as excluding the possibility that what is described and defined may include further elements, steps, etc. Meanwhile, when used herein, the term “approximately” and terms of its family (such as “approximate,” etc.) should be understood as indicating values very near to those which accompany the aforementioned term. That is to say, a deviation within reasonable limits from an exact value should be accepted, because a skilled person in the art will understand that such a deviation from the values indicated is inevitable due to measurement inaccuracies, etc. The same applies to the terms “about” and “around” and “substantially.”

What is claimed is:

1. An apparatus comprising:
a printed circuit board comprising a plurality of layers; and
a transformer structure implemented in the plurality of layers of the printed circuit board, comprising:
a transformer core formed in a hole through the plurality of layers of the printed circuit board;
a plurality of transformer primary conductive paths formed through the plurality of layers of the printed circuit board; and
a plurality of transformer secondary conductive paths formed through the plurality of layers of the printed circuit board.

2. The apparatus of claim 1, wherein the transformer core comprises a conductive layer plated onto an internal wall of the hole and a magnetic material layer plated over the conductive layer and surrounding an internal space of the hole.

3. The apparatus of claim 2, wherein the conductive layer comprises copper plating and the magnetic material layer plated over the conductive layer and comprising a plurality of layers including at least a layer of iron, and one or more layers of nickel and silver.

4. The apparatus of claim 2, wherein the plurality of transformer primary conductive paths extend through the printed circuit board and around a first angular portion of the transformer core and the plurality of transformer secondary conductive paths extend through the printed circuit board and around a second angular portion of the transformer core.

5. The apparatus of claim 1, wherein the plurality of transformer primary conductive paths and the plurality of transformer secondary conductive paths are arranged such that magnetic flux flow is radially orthogonal from the plurality of transformer secondary conductive paths to the plurality of transformer primary conductive paths.

6. The apparatus of claim 1, wherein the transformer core is circular in cross-section.

7. An apparatus comprising:
a printed circuit board comprising a plurality of layers;
a first transformer monument structure implemented in the plurality of layers of the printed circuit board and comprising:
a transformer core formed in a hole through the plurality of layers of the printed circuit board; and
a transformer primary conductive path formed around the transformer core through the plurality of layers of the printed circuit board;
a second transformer monument structure implemented in the plurality of layers of the printed circuit board spaced from the first transformer monument structure, and comprising:
a transformer core formed in a hole through the plurality of layers of the printed circuit board; and
a transformer secondary conductive path formed around the transformer core through the plurality of layers of the printed circuit board; and
a first magnetic material layer extending on a first outermost layer between the transformer core of the first transformer monument structure and the transformer core of the second transformer monument structure and a second magnetic material layer extending on a second outermost layer between the transformer core of the first transformer monument structure and the transformer core of the second transformer monument structure.

8. The apparatus of claim 7, wherein the transformer core of the first transformer monument structure and the transformer core of the second transformer monument structure comprises a conductive layer plated onto an internal wall of the hole and a magnetic material layer plated over the conductive layer.

9. The apparatus of claim 7, wherein the transformer primary conductive path comprises a plurality of first conductive portions each of which extends within a corresponding layer of the plurality of layers and circumscribes the transformer core of the first transformer monument structure and second conductive portions that extend in a via through the printed circuit board between first conductive portions in adjacent layers of the plurality of layers of the first transformer monument structure.

10. The apparatus of claim 7, wherein the transformer secondary conductive path comprises a plurality of first conductive portions each of which extends within a corresponding layer of the plurality of layers and circumscribes the transformer core of the second transformer monument structure and second conductive portions that extend in a via through the printed circuit board between first conductive portions in adjacent layers of the plurality of layers of the second transformer monument structure.

11. The apparatus of claim 10, wherein the via of the transformer primary conductive path and the via of the transformer secondary conductive path includes at least one cut or slot formed therein.

12. The apparatus of claim 7, wherein the transformer core of each of the first transformer monument structure and the second transformer monument structure includes a conductive layer plated onto an internal wall of the hole and a magnetic material layer plated over the conductive layer and comprising a plurality of layers including at least a layer of iron, and one or more layers of nickel and silver.

13. An apparatus comprising:
a printed circuit board having a plurality of layers;
a plurality of transformer cores implemented in the plurality of layers of the printed circuit board;
a first plated layer extending on a first outermost layer of the plurality of layers at a first end of the plurality of transformer cores;
a second plated layer extending on a second outermost layer of the plurality of layers at a second end of the plurality of transformer cores; and
an inner conductive layer formed in one or more of the plurality of layers of the printed circuit board between rows of the plurality of transformer cores, and between the first plated layer and the second plated layer, the inner conductive layer configured to receive a current to flow therethrough and for which a measurement is to be made.

14. The apparatus of claim 13, further comprising a hall effect sensor integrated into the printed circuit board in a gap formed in one of: a combination of the first plated layer, the second plated layer, or one of the plurality of transformer cores.

15. The apparatus of claim 14, wherein the gap extends along an entire width of: the first plated layer, the second plated layer, or one of the plurality of transformer cores.

16. The apparatus of claim 14, wherein the gap extends partially along a width of one of: the first plated layer and the second plated layer.

17. The apparatus of claim 16, wherein the hall effect sensor is at a position in the gap at a location corresponding to a strongest field point, and the hall effect sensor generates an output that indicates a measurement of an alternating current (AC) current or a direct current (DC) current.

18. The apparatus of claim 17, further comprising an analog-to-digital converter configured to receive the output of the hall effect sensor to generate digital values representing the output of the hall effect sensor.

19. The apparatus of claim 18, further comprising a digital filter configured to analyze the digital values output by the analog-to-digital converter to detect an arc fault.

20. An electromagnetic interference filter (EMI) filter comprising at least a first instance, a second instance of and a third instance of the apparatus of claim 13, wherein the first instance and the second instance of the apparatus are each configured to operate as a single inductor having an input and an output, inputs of the first instance and the second instance configured to receive a differential current signals as input, and outputs of the first instance and the second instance being coupled as input to the third instance of the apparatus, the third instance of the apparatus configured to operate as a mutually coupled inductors, wherein outputs of the third instance of the apparatus comprise EMI filtered differential current signals.
